(19) United States
(12) Patent Application Publication
(10) Pub. No.: US 2026/0026389 A1
(43) Pub. Date: Jan. 22, 2026

(54) APPARATUS WITH REDUCED INTERCONNECT PITCH AND METHODS OF MANUFACTURING THE SAME

(71) Applicant: Micron Technology, Inc., Boise, ID (US)

(72) Inventors: Manish Nayini, Hyderabad (IN); Quang Nguyen, Boise, ID (US); Tsung Han Chiang, Taichung (TW); Christopher Glancey, Boise, ID (US)

(21) Appl. No.: 19/271,357

(22) Filed: Jul. 16, 2025

Related U.S. Application Data
(60) Provisional application No. 63/673,532, filed on Jul. 19, 2024.

(51) Int. Cl. H01L 23/00; H01L 25/065

(52) U.S. Cl. CPC H01L 24/14; H01L 24/11; H01L 24/16; H01L 24/81; H01L 25/0657; H01L 24/13; H01L 24/17; H01L 2224/11452; H01L 2224/11462; H01L 2224/1147; H01L 2224/13082; H01L 2224/14133; H01L 2224/16145; H01L 2224/16227; H01L 2224/1713; H01L 2224/81193; H01L 2224/81815; H01L 2225/06513; H01L 2924/381; H01L 2924/3841

(57) ABSTRACT

Methods, apparatuses, and systems related to an apparatus configured to provide varied connection positions. The varied connection positions may be provided through an alternating pattern of pads and pedestals that are each configured to attach and electrically couple to complementary connection points on a connected device.

### CROSS-REFERENCE TO RELATED APPLICATION(S)

The present application claims priority to U.S. Provisional Patent Application No. 63/673,532, filed Jul. 19, 2024, the disclosure of which is incorporated herein by reference in its entirety.

### TECHNICAL FIELD

The disclosed embodiments relate to devices, and, in particular, to semiconductor devices with reduced interconnect pitch and methods of manufacturing the same.

### BACKGROUND

The current trend in semiconductor fabrication is to manufacture smaller and faster devices with a higher density of components for computes, cell phones, pagers, personal digital assistants, and many other products. However, decrease in circuit size and the increase in functionality can lead to certain challenges during manufacturing processes, such as due to decrease in separation between interconnects used for external communication. For illustrative purposes, FIG. 1A and FIG. 1B shows the difficulties associated with increasing circuit and interconnect density, through decreasing the circuit footprint and/or increasing the functionalities and the corresponding interconnects.

FIG. 1A illustrates a semiconductor assembly 100a having a first pitch distance 110a. The assembly 100a can include a substrate 102a physically attached and electrically coupled to a die 104a. For example, the assembly 100a can include a first interconnect 106a and a second interconnect 108a physically connecting and electrically coupling the substrate 102a and the die 104a.

The interconnects 106 and 108 can each include a pedestal extending from the die 104a, a pad on the substrate 102a, and a solder connecting the pedestal and the pad. For example, the first interconnect 106a can include a first substrate pad 112a on the substrate 102a, a first die pedestal 122a extending from the die 104a, and a first solder 132 attached to the first substrate pad 112a and the first die pedestal 122a. The second interconnect 108a can include a second substrate pad 114a on the substrate 102a, a second die pedestal 124a extending from the die 104a, and a second solder 134a attached to the second substrate pad 114a and the second die pedestal 124a.

The interconnects 106a and 108a can be separated by the first pitch distance 110a along a predetermined lateral distance. The first pitch distance 110a can be measured between reference locations (e.g., center portions) of the interconnects. However, given physical attributes of solder, the first and second solders 132a and 134a can have an actual separation distance 140 that is less than the first pitch distance 110a. For example, the surface tension of the solder material can allow the solders 132a and 134a to bulge and extend past the peripheral edges of the corresponding pads and pedestals, thereby providing the actual separation distance 140 less than the first pitch distance 110a.

For comparative purposes, FIG. 1B illustrates a semiconductor assembly 100b having a second pitch distance 110b that is less than the first pitch distance 110a. The assembly 100b can correspond to a narrower pitch device than the assembly 100a. The assembly 100b can include similar structures as the assembly 100a of FIG. 1A. For example, the assembly 100b can include a substrate 102b and a die 104b that are physically and electrically connected to each other through interconnects 106b and 108b. A first interconnect 106b can include a first substrate pad 112b, a first die pedestal 122b, and a first solder 132b. A second interconnect 108b can include a second substrate pad 114b, a second die pedestal 124b, and a second solder 134b.

In decreasing the separation distances between the interconnects, the actual separation distance 140 can provide a limitation. For example, at the limit illustrated in FIG. 1B, the second pitch distance 110b can cause the adjacent solders 132 and 134 to form a bridging contact 142, such as a continuous and integral structure. Due to the proximity, the solder structures can directly contact each other during reflow and then solidify with the bridging contact 142. As a result, the adjacent interconnects 106 and 108 can have an unintended electrical short. Such defect, resulting from decreasing the pitch distance, can damage the electrical circuits, cause errors in the targeted functionalities, and/or other similar undesirable issues.

### BRIEF DESCRIPTION OF THE DRAWINGS

FIG. 1A illustrates a semiconductor assembly having a first pitch distance.

FIG. 1B illustrates a semiconductor assembly having a second pitch distance.

FIG. 2A is a schematic top view of a semiconductor assembly in accordance with embodiments of the technology.

FIG. 2B is a cross-sectional view of the semiconductor assembly along dashed lines 2A-2A of FIG. 2A in accordance with embodiments of the technology.

FIG. 3A-FIG. 8 illustrate example phases for a manufacturing process in accordance with embodiments of the technology.

FIG. 9 is a flow diagram illustrating an example method of manufacturing an apparatus in accordance with an embodiment of the present technology.

FIG. 10 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, assemblies, or combinations thereof in accordance with the present technology can include interconnects that have alternating connection positions (e.g., heights). A pair of structures/devices, such as dies, substrates, interposers, or a combination thereof, can be attached to each other. The physical attachment and/or electrical coupling between the attached devices can be provided through interconnects. Each interconnect can include a pedestal extending from one of the attached devices extending toward a corresponding pad on the other of the attached devices. The pedestal can be attached to the pad through solder, a direct/fusion bonding joint, or the like. Adjacent instances of the interconnect can have pedestals extending from alternating devices. Stated differently, each of the devices can have an alternating pattern of pedestals and pads, and the attached devices can have offset or complementary patterns of the pedestals and pads. As a result, the physical connection between the pedestals and pads (e.g., the solders) of adjacent interconnects can be located at different heights.

Such offsets/differences in the heights of connection joints on adjacent interconnects can provide various benefits, including increased yield, decreased error and failure rates, and increased functionality. The offset heights of joints can prevent unintended shorts between adjacent interconnects, such as caused by bridging contacts (e.g., solders on adjacent interconnects merging during reflow), as interconnect pitch distance decreases. By preventing the unintended shorts, the offset heights of the connection joints can reduce the corresponding failure of devices/assemblies and any related functional errors. Moreover, the offset connection joints can allow the separation distance between interconnects to decrease further, thereby allowing denser/more interconnects for a given footprint or area. Further, the offset connection joints can prevent the unintended lateral shorts without decreasing the amount of solder for each connection. Accordingly, the offset connection joints can provide the same benefits while maintaining the benefits of retaining the solder volume, such as physical assistance or improvement in aligning the devices, stronger connections, lower connection failure rate, and the like.

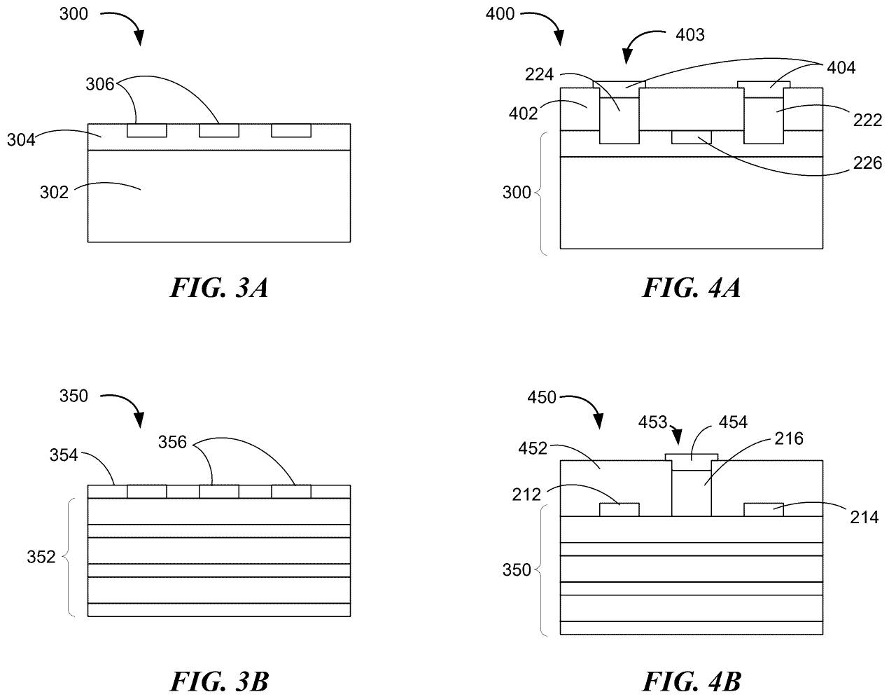

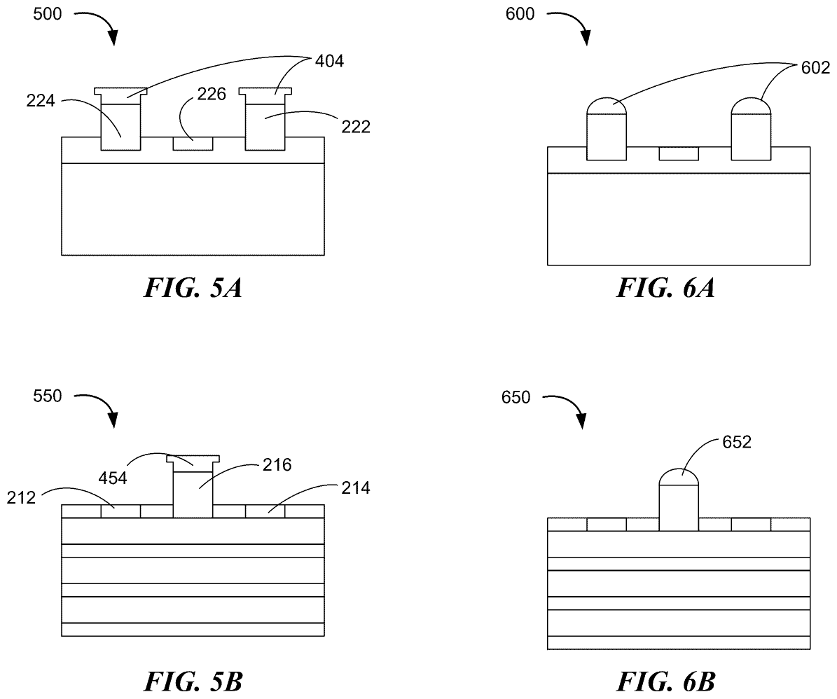

FIG. 2A is a schematic top view of a semiconductor assembly 200, and FIG. 2B is a cross-sectional view of the semiconductor assembly 200 along dashed lines 2A-2A of FIG. 2A, both in accordance with embodiments of the technology. Referring to FIG. 2A and FIG. 2B together, the semiconductor assembly 200 can include a substrate 202 physically attached and electrically coupled to a die 204. The substrate 202 can include a structure, such as a PCB, a semiconductor substrate, an interposer, a die (e.g., according to a die-to-die connection), or the like, that includes electrical circuits/components coupled to the die 204. Likewise, while the assembly 200 is described using the die 204 for illustrative purposes, it is understood that the die 204 may be replaced with other devices or structures, such as a PCB, a semiconductor substrate, an interposer, etc., that can be mounted on and/or connected to another structure.

The substrate 202 and the die 204 can be physically attached and electrically coupled to each other through interconnects, such as a first interconnect 206 and a second interconnect 208. The interconnects 206 and 208 can illustrate a physically adjacent pair of interconnects that provide different/separate electrical connections. Adjacent pairs of interconnects, such as the interconnects 206 and 208, can be separated by a pitch distance 210 measured along a lateral direction.

Each of the interconnects can include a connection pad on one of the structures and a corresponding pedestal extending from the other structure and toward the connection pad. The connection pad and the pedestal can be physically connected to each other, such as through a solder. Adjacent instances of the interconnects can have the pedestals extending from different structures. Stated differently, the substrate 202 can have an alternating pattern of pedestals and pads along one or more directions such that a pad is located between a pair of pedestals. The die 204 can also have an alternating pattern of pedestals and pads that is offset or complementary to the pattern of the substrate 202.

As an illustrative example, the substrate 202 can include a first substrate pad 212, a second substrate pad 214, a first substrate pedestal 216, and a second substrate pedestal 218. The alternating pattern can have (1) the first substrate pedestal 216 located between the first substrate pad 212 and the second substrate pad 214 (e.g., between adjacent instances of the pads) and (2) the second substrate pad 214 located between the first pedestal 216 and the second substrate pedestal 218 (e.g., between adjacent instances of the pedestals).

Similarly, the die 204 can include a first die pedestal 222, a second die pedestal 224, a first die pad 226, and a second die pad 228. The above-described alternating pattern of the die 204 can have the first die pad 226 located between the first die pedestal 222 and the second die pedestal 224 (e.g., between adjacent instances of the pedestals) and (2) the second die pedestal 224 located between the first die pad 226 and the second die pad 228 (e.g., between adjacent instances of the pads).

The above-described alternating pattern of the die 204 can be offset from and/or complementary to the offset pattern of the substrate 202. For example, when the die 204 is at a targeted position over the substrate 202, (1) the die pads can be directly over and overlap the substrate pedestals and (2) the die pedestals can be directly over and overlap the substrate pads. Accordingly, an adjacent pair interconnects (e.g., the interconnects 206 and 208) can have the pedestals extending from different structures toward the pad on the other structure. Using the example illustrated in FIG. 2B, the first interconnect 206 can have the first die pedestal 222 extending (downward) toward the first substrate pad 212, and the second interconnect 208 can have the first substrate pedestal 216 extending (upward) toward the first die pad 226.

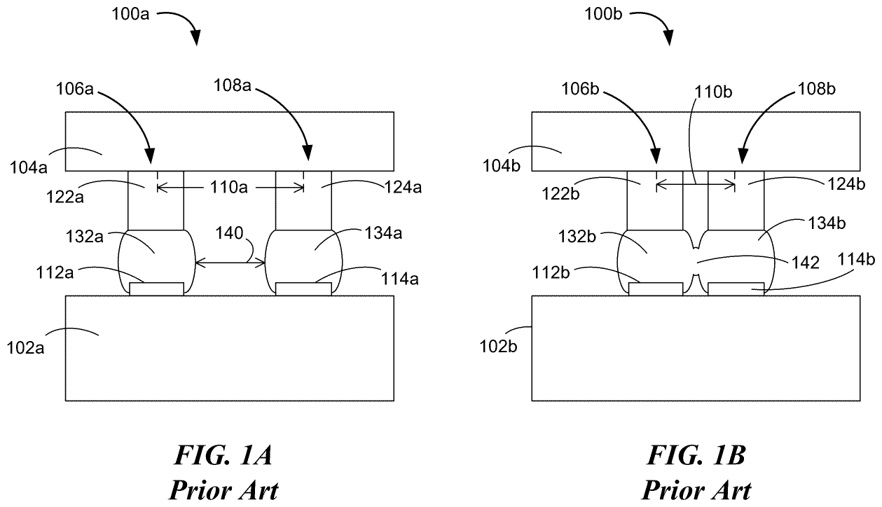

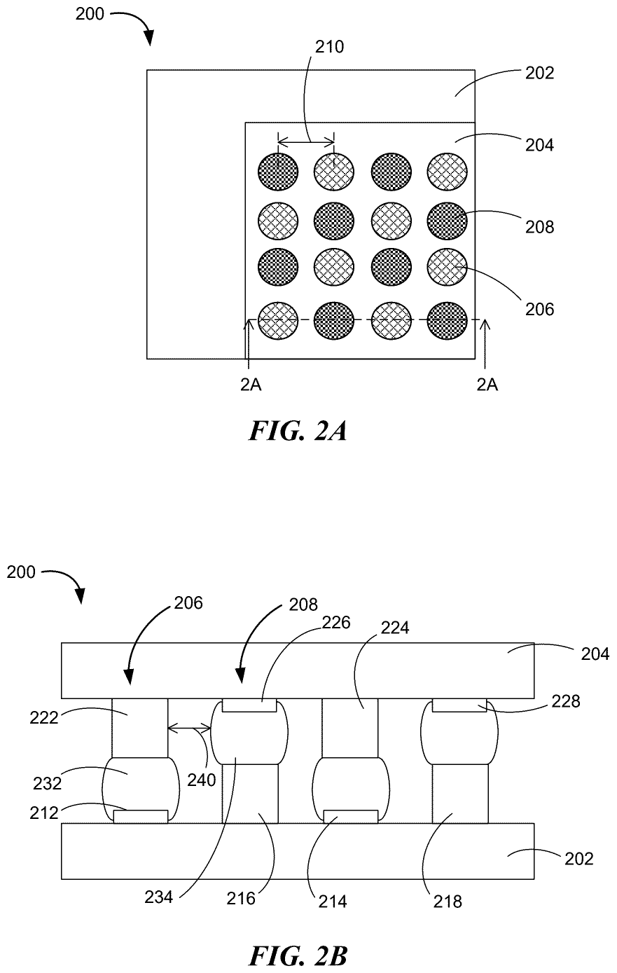

The alternating positions/patterns can provide alternating connection locations/heights. Continuing with the illustrated example, the first interconnect 206 can have a first solder 232 closer to the substrate 202 than the die 204, and the second interconnect 208 can have a second solder 234 closer to the die 204 than the substrate 202. Stated differently, the second solder 234 can be located higher than the first solder 232. The offset/different positions of the connections can provide an increase in the actual separation distance 240 in comparison to the actual separation distance 140 of FIG. 1B resulting from non-alternating connection locations.

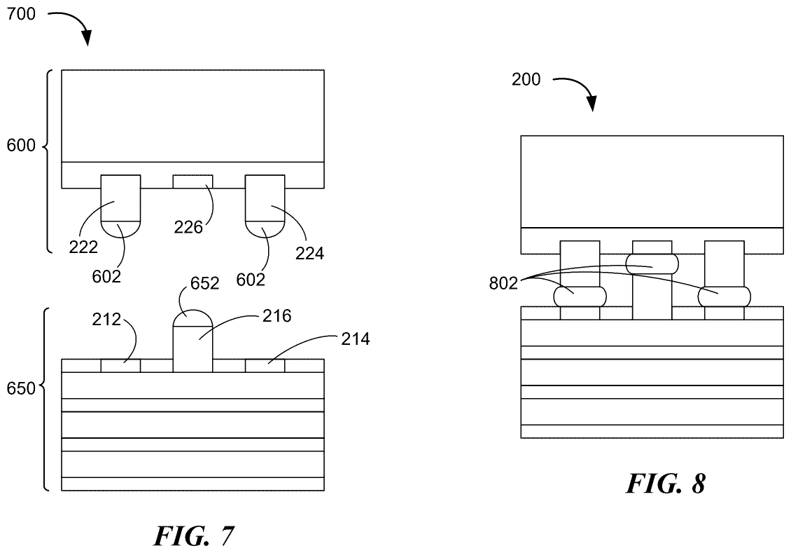

FIG. 3A-FIG. 8 illustrate example phases for a manufacturing process in accordance with embodiments of the technology. FIG. 3A illustrates a cross sectional view of a structure 300 (e.g., a semiconductor die or a portion of a semiconductor wafer) in accordance with embodiments of the technology. The structure 300 can correspond to a wafer subject to a back-end-of-line (BEOL) processing in manufacturing the die 204 of FIG. 2A. For example, the structure 300 can have a first body 302 (e.g., silicon substrate portion of the wafer/die) with a first cover layer 304 (e.g., a die/wafer seal layer, an oxide, and/or the like) over the first body 302 and forming a peripheral surface for the structure 300. The structure 300 can have a first set of connectors 306 on the first cover layer 304. A subset of the connectors 306 can correspond to the die pads (e.g., the die pads 226 and 228 of FIG. 2B), and a remaining set of the connectors 306 can be used to form the die pedestals (e.g., the die pedestals 222 and 224 of FIG. 2B).

FIG. 3B illustrates a cross sectional view of a structure 350 (e.g., a substrate structure) in accordance with embodiments of the technology. The structure 350 can correspond to an intermediate result in manufacturing the substrate 202 of FIG. 2A. Accordingly, the structure 350 can be complementary to the structure 300 of FIG. 3A. For example, the structure 350 can have a second body 352, such as core, intermediate wiring/signaling layers, oxide layers, and/or the like for a PCB, a semiconductor substrate portion for dies/wafers, etc. The structure 350 can have a second cover layer 354 (e.g., a solder resist for a PCB, a seal layer for a die, etc.) over the second body 352 and forming a peripheral surface for the structure 350. The structure 350 can have a second set of connectors 356 on the second cover layer 354. A subset of the connectors 356 can correspond to the substrate pads (e.g., the substrate pads 212 and 214 of FIG. 2B), and a remaining set of the connectors 356 can be used to form the substrate pedestals (e.g., the substrate pedestals 216 and 218 of FIG. 2B).

FIG. 4A illustrates a cross sectional view of a structure 400 (e.g., a semiconductor die or a portion of a semiconductor wafer) in accordance with embodiments of the technology. The structure 400 can correspond to a result of performing one or more manufacturing processes on the structure 300. For example, the structure 400 can have a mask 402 formed over the structure 300 (e.g., on the first cover layer 304 of FIG. 3A). The mask 402 can cover the subset of the first connectors 306 of FIG. 3A corresponding to the die pads and have openings over the remaining set of the connectors 306 corresponding to the die pedestals. The structure 400 can include pedestals formed within the openings. The pedestals can be attached to and/or integral with the corresponding connectors, such as by depositing metallic material (e.g., Copper, an alloy material, or other similar electrical conductors via chemical vapor deposition (CVD), electroplating, and/or the like) within/through the openings and onto the connectors exposed therein.

As an illustrative example, the mask 402 can cover the first die pad 226 and have openings 403 for forming the die pedestals 222 and 224. The die pedestals 222 and 224 can partially occupy the openings 403. Stated differently, the openings 403 in the mask 402 can have therein pre-flow solder 404 attached to and over the pedestals.

FIG. 4B illustrates a cross sectional view of a structure 450 (e.g., a substrate structure) in accordance with embodiments of the technology. The structure 450 can correspond to a result of performing one or more manufacturing processes on the structure 350. For example, the structure 450 can have a mask 452 formed over the structure 350 (e.g., on or an extension of the second cover layer 354 of FIG. 3B). The mask 452 can cover the subset of the second connectors 356 of FIG. 3B corresponding to the substrate pads and have openings 453 over the remaining set of the connectors 356 corresponding to the substrate pedestals. The structure 450 can include pedestals formed within the openings 453. The pedestals can be attached to and/or integral with the corresponding connectors, such as by depositing metallic material within/through the openings 453 and onto the connectors exposed therein.

As an illustrative example, the mask 452 can cover the first substrate pad 212 and the second substrate pad 214. The mask 452 can further have openings 453, including the opening used to form the first substrate pedestal 216. As in the structure 400 of FIG. 4A, the formed pedestals can partially occupy the openings 453 and the remainder can be occupied by pre-flow solder 454. Stated differently, the openings 453 in the mask 402 can have the pre-flow solder 454 attached to and over the first substrate pedestal 216.

FIG. 5A illustrates a cross sectional view of a structure 500 (e.g., a semiconductor die or a portion of a semiconductor wafer) in accordance with embodiments of the technology. The structure 500 can correspond to a result of performing one or more manufacturing processes on the structure 400 of FIG. 4A. For example, the structure 500 can correspond to a result of removing the mask 402 of FIG. 4A, thereby exposing the pads and the pedestals. For the illustrative example shown in FIG. 5A, the structure 500 can have the first die pad 226 and the die pedestals 222 and 224 exposed by removing the mask 402. The pre-flow solder 404 can also be exposed.

FIG. 5B illustrates a cross sectional view of a structure 550 (e.g., a substrate structure) in accordance with embodiments of the technology. The structure 550 can correspond to a result of performing one or more manufacturing processes on the structure 450 of FIG. 4B. For example, the structure 550 can correspond to a result of removing the mask 452 of FIG. 4B or a portion thereof, thereby exposing the pads and the pedestals. For the illustrative example shown in FIG. 5B, the structure 550 can have the substrate pads 212 and 214 and the substrate pedestal 216 exposed by removing the mask 452. The pre-flow solder 454 can also be exposed.

FIG. 6A illustrates a cross sectional view of a structure 600 (e.g., a semiconductor die or a portion of a semiconductor wafer) in accordance with embodiments of the technology. The structure 600 can correspond to a result of performing one or more manufacturing processes on the structure 500 of FIG. 5A. For example, the structure 600 can correspond to a result of reflowing the pre-flow solder 404 of FIG. 5A. Accordingly, the structure 600 can have solder bumps 602 on distal ends of the pedestals.

The structure 600 can correspond to the die 204 of FIG. 2A before assembly. Relatedly, FIG. 3A, FIG. 4A, FIG. 5A, and FIG. 6A can illustrate various processes/phases in manufacturing the die 204.

FIG. 6B illustrates a cross sectional view of a structure 650 (e.g., a substrate structure) in accordance with embodiments of the technology. The structure 650 can correspond to a result of performing one or more manufacturing processes on the structure 550 of FIG. 5B. For example, the structure 650 can correspond to a result of reflowing the pre-flow solder 454 of FIG. 5B. Accordingly, the structure 600 can have a solder bump 652 on a distal end of each of the pedestals.

The structure 650 can correspond to the substrate 202 of FIG. 2A before assembly. Relatedly, FIG. 3B, FIG. 4B, FIG. 5B, and FIG. 6B can illustrate various processes/phases in manufacturing the substrate 202. Moreover, FIG. 3B, FIG. 4B, FIG. 5B, and FIG. 6B can be complementary to FIG. 3A, FIG. 4A, FIG. 5A, and FIG. 6A, respectively.

FIG. 7 illustrates a cross sectional view of structures 600 and 650 aligned for assembly in accordance with embodiments of the technology. As described above, the structure 600 can correspond to the die 204 of FIG. 2A, and the structure 650 can correspond to the substrate 202 of FIG. 2A. Accordingly, the structures 600 and 650 can have alternating instances of pedestals and pads along one or more lateral directions. In other words, a pad can be located between adjacent pairs of pedestals and/or a pedestal can be located between adjacent pairs of pads. Further, the alternating patterns on the structures 600 and 650 can be offset from or complementary to each other. Accordingly, in aligning the structures 600 and 650, pedestals from one of the structures 600 and 650 can extend toward corresponding pads on the other of the structures 600 and 650. For example, the first die pedestal 222 of the die 204 can be positioned directly over or overlap the first substrate pad 212 of the substrate 202; the first die pad 226 of the die 204 can be positioned directly over or overlap the first substrate pedestal 216 of the substrate 202; and/or the second die pedestal 224 of the die 204 can be positioned directly over or overlapping the second substrate pad 214 of the substrate 202.

FIG. 8 illustrates a cross sectional view of the semiconductor assembly 200 in accordance with embodiments of the technology. The semiconductor assembly 200 correspond to a result of performing one or more manufacturing processes on the structures 600 and 650 of FIG. 7. For example, the semiconductor assembly 200 can be a result of lowering the structure 600 toward the structure 650 such that the solder bumps 602 and 652 of FIG. 7 contact the corresponding pads according to the alignment illustrated in FIG. 7. The contacting solder bumps 602 and 652 can be reflowed, such as by exposing the solder bumps to elevated temperatures, to form alternating solder connections 802. The alternating solder connections 802 can include the first solder 232 of FIG. 2B and the second solder 234 of FIG. 2B. As described above, the alternating solder connections 802 can have different positions/heights between adjacent pairings according to the alternating locations of the pedestals.

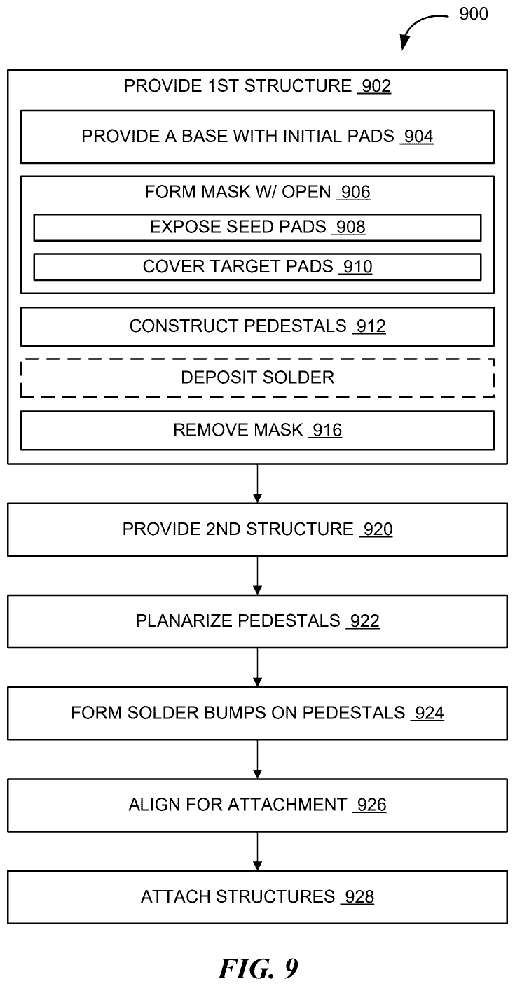

FIG. 9 is a flow diagram illustrating an example method 900 of manufacturing an apparatus in accordance with an embodiment of the present technology. The example method 900 can be for manufacturing the semiconductor assembly 200. For example, the method 700 can correspond to the manufacturing processes illustrated in FIG. 3A-FIG. 8.

The method 900 can include providing a first structure (e.g., the die 204 of FIG. 0.2B), such as a semiconductor wafer/device, a PCB structure, and/or the like as illustrated at block 902. Providing the first structure can correspond to the phase illustrated at FIG. 3A or FIG. 6A or a derivative thereof. For example, the provided structure can include the die pads on a die surface with die pedestals extending from the die surface. In some embodiments, the provided structure can have solder bumps on distal ends of the die pedestals.

Providing the first structure can include positioning the structure for a subsequent process, such as for aligning the first structure with another structure. Additionally or alternatively, providing the first structure can include manufacturing the first structure or similarly adjusting a portion thereof. For example, at block 904, a base can be provided with initial pads, such as the first body 302 of FIG. 3A having the first connectors 306 of FIG. 3A.

As shown at block 906, a mask having one or more openings may be formed over the base. For example, as discussed above with respect to FIG. 4A, the mask 402 of FIG. 4A may be deposited over the structure 300 of FIG. 4B. Subsequently, openings may be formed in the mask 402, such as by etching away targeted locations, to expose a set of seed pads within the first connectors 306 as illustrated in block 908. Other connectors, such as targeted pads corresponding to the die pads, can remain covered by the mask 402 as illustrated in block 910. In some embodiments, openings may be formed over and exposing every other connector in the first connectors 306 along one or more lateral directions.

The manufacturing process can include constructing the pedestals as shown at block 912. For example, metallic material may be deposited through the openings and directly on the exposed seed pads. Accordingly, the die pedestals can be formed directly on or integral with the seed pads and occupy the openings in the mask. In some embodiments, solder material may be deposited over the pedestals and filling top portions of the openings as described above with respect to FIG. 4A.

At block 916, the manufacturing process can include removing the mask. The resulting structure (e.g., the structure 500 of FIG. 5A) can have the targeted pads (e.g., the die pad 226 of FIG. 5A) and peripheral surfaces of the pedestals (e.g., the pedestals 222 and 224 of FIG. 5A) exposed.

The manufacturing process can further include providing a second structure for assembly with the first structure as illustrated at block 920. The provided second structure can include a PCB substrate or a semiconductor structure (e.g., an interposer, a common wafer, a semiconductor chip, etc.) as described above. For example, the provided second structure can include the substrate 202 of FIG. 2B. Similar to the processing described for block 902, providing the second structure can include positioning the second structure and/or manufacturing or modifying the second structure. Manufacturing the second structure can correspond to FIG. 3B, FIG. 4B, FIG. 5B, and/or FIG. 6B. Accordingly, the provided second structure can have pads (e.g., the substrate pads) on a substrate surface and pedestals (e.g., the substrate pedestals) extending from the substrate surface and peripheral surfaces of the pads. Further, the provided second structure may have solder bumps at distal ends of the substrate pedestals.

In some embodiments, manufacturing the second structure can be performed in parallel or simultaneously with that of the first structure. For example, the first and second structure can correspond to semiconductor devices that are formed on different portions of a common semiconductor wafer. Accordingly, the mask can be applied and removed as a continuous layer that covers the different portions, and the pedestals can be constructed/formed through a common metallization or depositing process.

The method may include planarizing the pedestals on the first and second structures as illustrated in block 922. For example, the provided first and second structures can be positioned side-by-side with their reference surfaces (e.g., surfaces having the pads and pedestals thereon) coplanar with each other. A common planarizing process can level the pedestals on both the first and second structures such that the first and second structures have a common height from the reference surfaces. The method may include depositing masks or other layers between the pedestals to provide structural reinforcement and/or the common height during the planarization process. In other embodiments, such as when the first and second structures are semiconductor devices corresponding to different portions of a common wafer, the planarization process can be performed before removing the mask.

At block 924, the method can include forming solder bumps on distal ends of the pedestals. The solder bumps can be formed by reflowing the solder material, as described above with respect to FIG. 6A and FIG. 6B. In some embodiments, forming solder bumps can include depositing solder material at distal ends of planarized pedestals.

At block 926, the method can include aligning the first and second structures for attachment. The first structure can be positioned over the second structure with the respective reference surfaces facing each other. The first structure can be positioned with its pedestals overlapping and extending toward corresponding pads on the second structure. Likewise, the first structure can be positioned such that the pads thereon can overlap with the corresponding pedestals on the second structure extending toward the pads. For example, the die 204 can be positioned over the substrate 202 such that (1) the die pedestals 222 and 224 overlap extend downward toward the respective substrate pads 212 and 214 and (2) the substrate pedestals 216 and 218 are overlapped by and extend upward toward the respective die pads 226 and 228. In some embodiments, the solder bumps on the distal ends of the pedestals can contact the interfacing surfaces of the corresponding pads. In other embodiments, the pedestals can directly contact the corresponding pads.

The method can include attaching the first and second structures, as illustrated at block 928, according to the alignment. For example, the structures can be attached by reflowing the solder, fusing the pads and pedestals, or other similar processes.

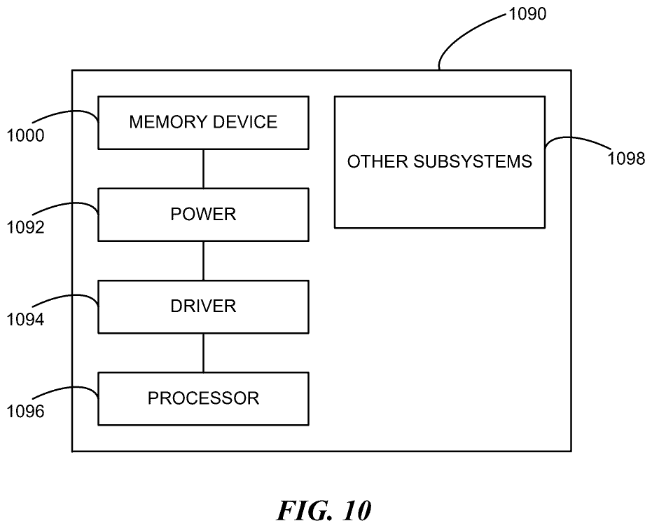

FIG. 10 is a schematic view of a system that includes an apparatus in accordance with embodiments of the present technology. Any one of the semiconductor devices described above with reference to FIGS. 2A-9 can be incorporated into any of a myriad of larger and/or more complex systems, a representative example of which is system 1090 shown schematically in FIG. 10. The system 1090 can include a semiconductor device 1000 (“device 1000”) (e.g., a semiconductor device, package, and/or assembly), a power source 1092, a driver 1094, a processor 1096, and/or other subsystems or components 1098. The device 1000 can include features generally similar to those devices described above. The resulting system 1090 can perform any of a wide variety of functions, such as memory storage, data processing, and/or other suitable functions. Accordingly, representative systems 1090 can include, without limitation, hand-held devices (e.g., mobile phones, tablets, digital readers, and digital audio players), computers, and appliances. Components of the system 1090 may be housed in a single unit or distributed over multiple, interconnected units (e.g., through a communications network). The components of the system 1090 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” and “having” are used throughout to mean including at least the recited feature(s) such that any greater number of the same feature and/or additional types of other features are not precluded. Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A semiconductor assembly, comprising:
a substrate having a substrate surface with:
a first substrate pad and a second substrate pad on the substrate surface, and
a substrate pedestal on and extending upward from the substrate surface, wherein the substrate pedestal is located between the first and second substrate pads;
a semiconductor die over and connected to the substrate, the semiconductor die having:
a die surface facing the substrate surface,
a first die pedestal extending downward from the die surface and overlapping the first substrate pad,
a second die pedestal extending downward from the die surface and overlapping the second substrate pad, and
a die pad on the die surface and overlapping the substrate pedestal, wherein the die pad is located between the first and second die pedestals;
a first solder connection connecting the first die pedestal to the first substrate pad;
a second solder connection connecting the second die pedestal to the second substrate pad, wherein the first and second solder are at a first height; and
a third solder connection connecting the die pad to the substrate pedestal, wherein the third solder connection is at a second height different from the first height.

2. The semiconductor assembly of claim 1, wherein the substrate is a printed circuit board (PCB).

3. The semiconductor assembly of claim 1, wherein the semiconductor die is a first die and the substrate is a second die.

4. The semiconductor assembly of claim 1, wherein:
the first and second solder are closer to the substrate than the semiconductor die; and
the third solder is closer to the semiconductor die than the substrate.

5. The semiconductor assembly of claim 1, wherein:
the first die pedestal, the first solder, and the first substrate pad correspond to a first interconnect;
the second die pedestal, the second solder, and the second substrate pad correspond to a second interconnect;
the die pad, the third solder, and the substrate pedestal correspond to a third interconnect,
wherein the first, second, and third interconnects electrically couple the semiconductor die to the substrate,
wherein the first second, and third interconnect are positioned according to a pitch distance measured between reference locations on pedestals and pads, and
wherein a minimum separation distance between adjacent interconnects are between a solder on one of the adjacent interconnect and a pedestal on another of the adjacent interconnects.

6. An apparatus, comprising:
a base having a base surface;
a pad on the base surface, wherein the pad has a connection surface configured to provide a first external electrical interface; and
a pedestal on and extending away from the base surface and past the pad, wherein the pedestal is directly adjacent to the pad according to a connection pitch and configured to provide a second external electrical interface.

7. The apparatus of claim 6, wherein the pedestal is a first pedestal, the apparatus further comprising:
a second pedestal on and extending away from the base surface and past the pad, wherein the pad is located between the first and second pedestals according to the connection pitch.

8. The apparatus of claim 6, wherein the base is a semiconductor substrate.

9. The apparatus of claim 6, wherein the base includes a Printed Circuit Board (PCB) core.

10. The apparatus of claim 6, wherein the apparatus comprises an interposer.

11. The apparatus of claim 6, further comprising:
solder bump on a distal end of the pedestal.

12. A method of manufacturing an apparatus, the method comprising:
providing a base structure having a base surface and a set of initial pads arranged laterally on the base surface according to a pitch distance;
covering the base surface with a mask layer,
wherein the mask layer includes openings that expose seed pads within the set of initial pads,
wherein the exposed seed pads are directly adjacent to and/or disposed between target pads that are covered by the mask layer;
forming pedestals directly on the exposed seed pads based on depositing metallic material and within the openings, wherein the formed pedestal extends from the base surface and past top surface of the target pads; and
removing the mask to expose the target pads and peripheral surfaces of the pedestals.

13. The method of claim 12, wherein the provided base structure is a semiconductor wafer.

14. The method of claim 12, wherein the provided base structure includes a Printed Circuit Board (PCB) core.

15. The method of claim 12, wherein the base structure with the target pads and the pedestals is a first structure having first target pads and first pedestals wherein the first target pads and the first pedestals are alternatingly positioned along a lateral direction with the first target pads located between an adjacent pair of the first pedestals, the method further comprising:
providing a second structure having second target pads on a second surface and second pedestals extending from the second surface;
aligning the first structure relative to the second structure with (1) the base surface facing the second surface, (2) the first pedestals overlapping with and extending toward the second target pads, and (3) the second pedestals overlapping with and extending toward the first target pads; and
attaching the first and second structures based on (1) attaching the first pedestals to the second target pads and (2) attaching the second pedestals to the first target pads, wherein adjacent instances of connection joints between pads and pedestals are at different heights.

16. The method of claim 15, further comprising:
positioning the first and second structures side-by-side; and
planarizing the first and second pedestals together using the side-by-side positioning of the first and second structures, wherein the planarized first and second pedestals have a common height.

17. The method of claim 15, wherein:
the first and second structures are both semiconductor devices; and
providing the second structure includes manufacturing the second structure from a semiconductor wafer.

18. The method of claim 17, wherein:
providing the first structure includes manufacturing the first structure from the semiconductor wafer; and
the first and second pedestals are formed together through a common metallic deposition process.

19. A method of manufacturing an apparatus, the method comprising:
providing a first structure having first target pads on a first surface and first pedestals extending from the first surface,
wherein the first target pads and the first pedestals are alternatingly positioned along a lateral direction with the first target pads located between an adjacent pair of the first pedestals,
wherein the first structure further includes first solder bumps that are each located on a distal end of a corresponding one of the first pedestals;
providing a second structure having second target pads on a second surface and second pedestals extending from the second surface,
wherein the second target pads and the second pedestals are alternatingly positioned along the lateral direction with the second target pads located between an adjacent pair of the second pedestals,
wherein the second structure further includes second solder bumps that are each located on a distal end of a corresponding one of the second pedestals;
aligning the first structure relative to the second structure with (1) the first solder bumps contacting the second target pads and (2) the second solder bumps contacting the first target pads; and
attaching the first and second structures based on reflowing the first and second solder bumps.

20. The method of claim 19, further comprising:
planarizing the first and second pedestals together to provide a common height for the planarized first and second pedestals, wherein the planarization is conducted based on having the first and second surfaces coplanar to each other.
